(19) United States
(12) Patent Application Publication
(10) Pub. No.: US 2007/0052560 A1
(43) Pub. Date: Mar. 8, 2007

(54) Bit-stream watermarking

(76) Inventors: Minne Van Der Veen, Eindhoven (NL); Aweke Negash Lemma, Eindhoven (NL); Alphons Antonius Maria Lambertus Eindhoven, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/557,681

(22) PCT Filed: May 19, 2004
(86) PCT No.: PCT/IB04/50744

§ 371 Date: Nov. 22, 2005

(30) Foreign Application Priority Data
May 28, 2003 (EP) 03101546.4

(51) Int. Cl. H03M 7/34

(52) U.S. Cl. 341/51

(57) ABSTRACT

The present invention relates to methods, devices, a media signal and a recorded medium for watermarks embedded in the sub-band domain of compressed media. Watermarks (w[n]) are embedded into the sub-band signals (xᵢ₋₁[n], xᵢ[n], xᵢ₊₁[n]) of at least one selected sub-band of a compressed bit-stream (bₖ) using a watermark inserting unit (18). In this way there is no need to fully decode and re-encode the media signal for embedding the watermark. The watermark is embedded in selected sub-bands (e.g. sub-bands 7-15 of 32). In a preferred embodiment, the selected sub-bands are upsampled before embedding and downsampled therafter to avoid aliasing. The invention also allows embedding multiple watermarks in different sub-bands (e.g. one watermark in sub-bands 7-11, and a different watermark in sub-bands 12-16).

### TECHNICAL FIELD

The present invention generally relates to the field of embedding additional data in a media signal and more particularly to the field of providing watermarking in compressed media.

### DESCRIPTION OF RELATED ART

The illicit distribution of copyright material deprives the holder of the copyright the legitimate royalties for this material, and could provide the supplier of this illicitly distributed material with gains that encourages continued illicit distributions. In light of the ease of transfer provided by the Internet, content material that is intended to be copyright protected, such as artistic renderings or other material having limited distribution rights are susceptible to wide-scale illicit distribution. The MP3 format for storing and transmitting compressed audio files has made a wide-scale distribution of audio recordings feasible. For instance, a 30 or 40 megabyte digital audio recording of a song can be compressed into a 3 or 4 megabyte MP3 file. Using a typical 56 kbps dial-up connection to the Internet, this MP3 file can be downloaded to a user's computer in a few minutes. This means that a malicious party could provide a direct dial-in service for downloading MP3 encoded song. The illicit copy of the MP3 encoded song can be subsequently rendered by software or hardware devices or can be decompressed and stored on a recordable CD for playback on a conventional CD player.

A number of techniques have been proposed for limiting the reproduction of copy-protected content material. The Secure Digital Music Initiative (SDMI) and others advocate the use of “digital watermarks” to identify authorised content material.

Digital watermarks can be used for copy protection according to the scenarios mentioned above. However, the use of digital watermarks is not limited to this but can also be used for so-called forensic tracking, where watermarks are embedded in e.g. files distributed via an Electronic Content Delivery System, and used to track for instance illegally copied content on the Internet. Watermarks can furthermore be used for monitoring broadcast stations (e.g. commercials); or for authentication purposes etc.

There are several known techniques for embedding data in the raw uncompressed audio signal. But as has been outlined above, a lot of audio is provided in the compressed domain. Examples of such formats are MPEG, AAC and WMA.

In view of the occurrence of compressed audio such as MP3, there is thus a need for effectively embedding watermarks in such compressed samples. The process of compressing an audio signal is called encoding. After encoding, the resulting signal is often called the bit-stream. Bit-stream watermarking refers to the process of embedding a watermark in a compressed audio signal.

Bit-stream watermarking is generally known within the art. For instance WO-99/29114 describes watermarking in scale factor bands. Scale factors are bit-stream signal parameters used in the sub-band domain for optimizing the coding efficiency. However, the prior art does describe a system that works with additive watermarks only.

There is thus a need for a generic solution that can be used for all types of watermark embedding including additive and multiplicative watermarking in relation with any sub-band based audio coder.

### SUMMARY OF THE INVENTION

It is thus an object of the present invention to provide a generic solution for a bit-stream watermark such that not only additive watermarks but also other kinds of watermarks can be implemented in the bit-stream domain.

According to a first aspect of the present invention, this object is achieved by a method of embedding additional data into the bit-stream of a media signal comprising the steps of:

obtaining a number of sub-band bit-streams of an input bit-stream; converting at least one sub-band bit-stream into a primary sub-band signal that is semantically compatible with said intended additional data; and

modifying said sub-band signal with said additional data, in order to provide an output bit-stream carrying said embedded additional data.

According to a second aspect of the present invention, this object is also achieved by a method of detecting additional data provided in a media signal, comprising the steps of:

selecting a frequency range at least approximately corresponding to at least one sub-band signal where the additional data is embedded; and

detecting the additional data.

According to a third aspect of the present invention, this object is furthermore achieved by a device for embedding additional data in the bit-stream of a media signal comprising:

a unit for converting at least one sub-band bit-stream, which is to carry additional data and is related to an input bit-stream, into a primary sub-band signal semantically compatible with the intended additional data; and

at least one data inserting unit for modifying said sub-band signal with additional data for provision in an output bit-stream.

According to a fourth aspect of the present invention, this object is furthermore achieved by a device for detecting additional data provided in a media signal, comprising:

a control unit for selecting a frequency range at least approximately corresponding to at least one sub-band where the additional data is provided, and an additional data detector for detecting the additional data.

According to a fifth aspect of the present invention, this object is also achieved by a media signal having additional embedded data, wherein the additional data is embedded in at least one sub-band signal of the media signal.

According to a sixth aspect of the present invention, this object is also achieved by a recorded medium having additional embedded data in a media signal, wherein the additional data is embedded in at least one sub-band signal of the media signal.

Claims 2 and 19 are directed towards splitting the input bit-stream into a number of sub-band bit-streams.

Claims 3 and 20 are directed towards converting the sub-band signals to sub-band bit-streams and combining these including modified and unmodified sub-band bit-streams for providing an output bit-stream.

Claim 4 is directed towards delaying sub-band bit-streams not receiving additional data.

Claim 5 is directed towards selecting sub-bands that are to receive additional data.

claims 7 and 21 are directed towards upsampling and downsampling sub-band signals before and after embedding additional data for avoiding aliasing distortions.

Claims 9 and 23 are directed towards providing extra energy from a sub-band signal, which has received additional data, in neighbouring sub-bands in order to avoid aliasing distortions.

Claims 11, 12 and 24 are directed towards combining sub-band signals that are to receive additional data and then splitting these signals in order to avoid aliasing distortions.

Claims 15, 16, 27 and 28 are directed towards splitting a received media bit-stream into a number of sub-band bit-streams, converting bit-streams including additional data into at least one sub-band signal and detecting the additional data in the sub-band signal.

Claims 17 and 29 are directed towards combining sub-band signals before detecting additional data.

The present invention has the advantage of enabling detection of additional data both in the decompressed domain, (e.g. on wav-files or PCM signals), as well as in the compressed domain such as mp3 or AAC or in other audio compression formats. Moreover, the embedding of the additional data is made in such a way that there is no need to fully decode and re-encode the audio signal. This does not only mitigate the introduction of unnecessary additional artefacts but also results in a less complex solution. This enables one to use the watermarking system for forensic tracking applications, where watermarks are embedded in e.g. files distributed via an Electronic Content Delivery System, and used to track for instance illegal copied content on the Internet. Watermarks embedded according to the present invention can furthermore be used for monitoring broadcast stations or for authentication purposes.

The general idea behind the invention is thus to embed additional data, like a watermark, in the bit-stream by partially decoding a portion of the bit-stream signal into semantically relevant plurality of sub-band signals, such that at least one of the sub-band signals is provided with said additional data.

These and other aspects of the invention will be apparent from, and elucidated with reference to, the embodiments described hereinafter.

### BRIEF DESCRIPTION OF THE DRAWINGS

The present invention will now be explained in more detail in relation to the enclosed drawings, by way of example, where

FIG. 1 shows a block schematic of a device for embedding a watermark in a bit-stream according to a first embodiment of the present invention,

FIG. 2A shows a block schematic of a watermark inserting unit according to a first embodiment of the invention provided in the device of FIG. 1,

FIG. 2B shows a block schematic of an embedder unit provided in the watermark inserting unit of FIG. 2A,

FIG. 3 shows a flow chart of a method of embedding a watermark into a bit-stream according to the invention,

FIG. 4 shows a flow chart of a method of detecting an embedded watermark according to the invention,

FIG. 5 shows a block schematic of a watermark inserting unit according to a second embodiment of the present invention,

FIG. 6 shows a block schematic of a watermark inserting unit according to a third embodiment of the present invention,

FIG. 7 shows a block schematic of a watermark inserting unit according to a fourth and preferred embodiment of the present invention,

FIG. 8 shows a block schematic of a first watermark detecting device according to the invention,

FIG. 9 shows a block schematic of a second watermark detecting device according to the invention,

FIG. 10 shows a block schematic of a third watermark detecting device according to the invention,

FIG. 11 shows an optical disc on which a media signal with an embedded watermark according to the invention is stored,

FIG. 12A shows a window shaping function of the raised cosine type used when embedding watermarks, and

FIG. 12B shows a window shaping function of the bi-phase type used when embedding watermarks.

### DETAILED DESCRIPTION OF EMBODIMENTS

The present invention relates to the field of providing additional data in a compressed media signal such as a compressed (or a bit-stream) audio.

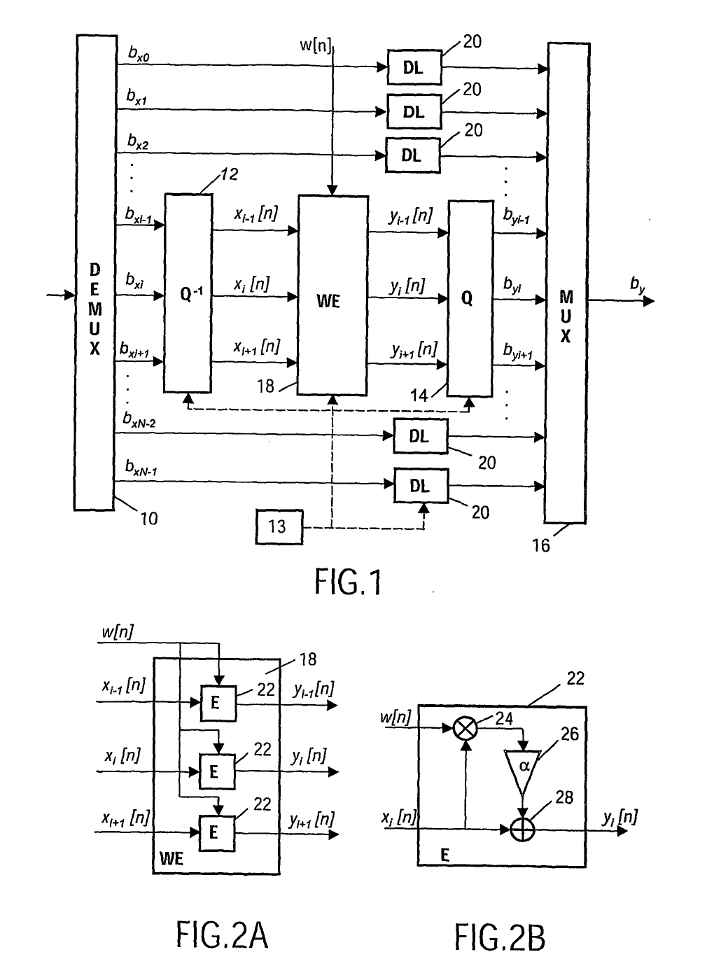

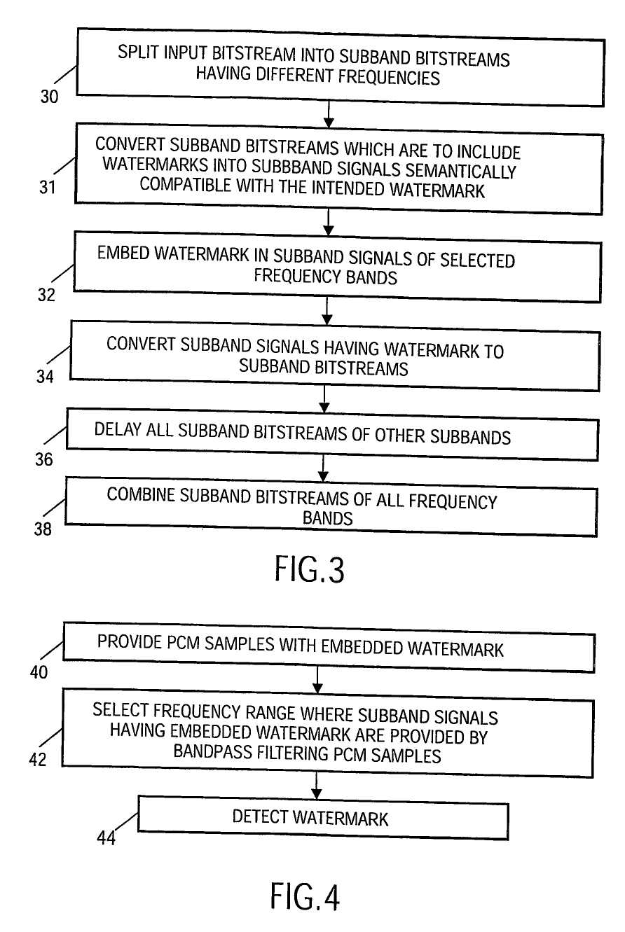

FIG. 1 shows a block schematic of a device according to a first embodiment of the invention for embedding a watermark in the bit-stream domain of an audio signal. The functioning of the device will now be described with reference also being made to FIG. 3, which shows a flow chart of a method according to which the device works. The device includes a demultiplexing unit 10 receiving an input bit-stream bₓ of a signal in order to provide N sub-band bit-streams bₓₒ . . . b_{xN-1}, step 30. The sub-band bit-streams bₓᵢ₋₁, bₓᵢ and bₓᵢ₊₁ that are intended to carry a watermark signal are provided to a dequantisation unit 12 applying an inverse quantisation function Q⁻¹, step 31. In this way sub-band signals are created that are semantically compatible with the intended watermark. The dequantisation unit is typically a zero order hold circuit, which provides amplitude quantised and appropriately scaled and filtered sub-band signals xᵢ₋₁[n], xᵢ[n], and xᵢ₊₁[n]. Subsequently, these sub-band signals are supplied to a watermark inserting unit 18, which also receives a watermark signal w[n] to be inserted in all of the sub-band signals xᵢ₋₁[n], xᵢ[n], and xᵢ₊₁[n] in order to generate sub-band watermarked signals yᵢ₋₁[n], yᵢ[n] and yᵢ₊₁[n], step 32. It should be noted here that the watermark or the additional data is embedded in three sub-bands only as a way of example. In an actual system, the embedding may be done on less or more sub-band signals than displayed in this example. The watermark inserting unit 18 supplies watermarked sub-band signals yᵢ₋₁[n], yᵢ[n], and yᵢ₊₁[n] to a quantisation unit 14, which re-scales them and converts them back into sub-band bit-streams, step 34. The three output bit-streams b_{yi-1}, b_{yi}, and b_{yi+1} are then supplied directly to a multiplexing unit 16 together with the unmodified bit-streams bₓₒ . . . bₓᵢ₋₂, bₓᵢ₊₂ . . . b_{xN-1}, which are supplied via respective delay units 20, step 36. The delay units are provided in order to take account for the delay caused by the watermarking process, so that non-watermarked sub-band bit-streams are provided in phase with watermarked bit-streams. Each delay unit supplies the appropriately delayed bit-streams to the multiplexing unit 16. The MUX unit 16 multiplexes the provided sub-band bit-streams into an overall output bit-stream b_{y} that is compatible with the format of the original input bit-stream signal bₓ, step 38. The embedding device also includes a control unit 13 that controls on which sub-band bit-streams the watermark inserting unit 18, the dequantisation unit 12 and the quantisation unit 14 are to be used. It also controls on which sub-band bit-streams delays are to be applied. In the figure, the control signals are indicated with dashed lines, where only one such line is shown for one delay unit. It should however be realised that the control unit controls the delay provided for all sub-band bit-streams. The dequantisation unit 12, as mentioned above, uses the scale factors for producing the sub-band signals xᵢ₋₁[n]−xₓ₊₁[n]. These scale factors are provided together with the corresponding sub-band signals and used in reconstructing the watermarked sub-band bit-streams in the quantisation unit 14. Also these scale factors are delayed with the same delay as the non-watermarked sub-band bit-streams. These scale factors and the delay units used for their delay have however been omitted from FIG. 1 in order to provide a better understanding of the invention. It should also be realised that these scale factors are not strictly necessary in the invention. The dequantisation unit 12 can therefore as an alternative just as well provide unscaled sub-band signals, in which a watermark is embedded.

FIG. 2A shows a block schematic of the watermark inserting unit 18 used in FIG. 1. The watermark inserting unit includes three embedder E units 22, each of which respectively receives a sub-band signal xᵢ₋₁[n], xᵢ[n], and xᵢ₊₁[n] as well as the watermark w[n] and embeds the watermark in this signal in order to provide the corresponding watermarked sub-band signal yᵢ₋₁[n], yᵢ[n] and yᵢ₊₁[n]. In this figure the watermark signal w[n] fed to the individual embedder units is identical. In practise the watermark signal may differ for different sub-band signals. I.e. different sub-band signals are modulated with different information signals.

FIG. 2B shows a block schematic of one preferred example of the embedder unit 22 used in the watermark inserting unit 18 for one of the sub-bands i. The embedder unit 22 includes a multiplying unit 24, which multiplies the watermark with the sub-band sample xᵢ[n] selected for containing a watermark. The output of the multiplying unit 24 is connected to a gain control unit 26, which in turn is connected to an adding unit 28, which also receives the input sub-band sample xᵢ[n]. The output of the adding unit 28 is then the sub-band signal yᵢ[n]. This method of watermarking is also known as envelope modulation watermarking, which is described in more detail in, “A temporal domain audio watermarking technique”, by Aweke Negash Lemma, Javier Aprea, Werner Oomen and Leon van de Kerkhof, IEEE Transactions on Signal Processing, April 2003, Vol. 51, page 1088-1097, which is herein incorporated by reference.

How the actual watermarking takes place will now be described in somewhat more detail. The sub-band signal is watermarked in the temporal domain through envelope modulation. The input signal is here modulated with the watermark and the watermark signal is weighted with a factor α.

Before modifying the input signal x[n] with the watermark, a so-called host modifying signal is generated according to:
w_{b}[n]=w[n](x[n]*h[n]),

Thus, the host modifying signal w_{b}[n] is provided by multiplying (modulating) the bandpass filtered version of an input signal x[n] with the watermark signal w[n]. Here h[n] represents the impulse response of the bandpass filter H. In the present invention bandpass filtering may or may not be included. The selection of the different sub-band signals in some sense already discriminates between frequencies and performs some kind of bandpass filtering. Therefore this filter may not be strictly necessary when performing the actual watermarking.

The watermark signal is then weighted with a scaling factor α and added to the original signal according to:
y[n]=x[n]+αw_{b}[n],

As can be seen from FIG. 2B, the watermark embedder unit 22 provides precisely this type of output signal as described above, but where the output signal has been denoted by yᵢ[n] instead of y[n]. The above mentioned watermark embedding is thus done by the multiplying unit 24, scaling unit 26 and adding unit 28 of FIG. 2B.

The watermark signal w[n] is constructed from an initially generated finite length, zero mean, uniformly distributed random sequence wₛ[k], where
wₛ[k]ε[−1, 1] for k=0, 1, . . . , L_{w}−1,
and L_{w} is the length of the sequence. Subsequently the sample rate of this sequence is increased with a factor Tₛ, according to:

$${\tilde{w}}_{s} [ n ] = \{ \begin{matrix}{w}_{s} [ n / {T}_{s} ] & for n = 0 , \pm {T}_{s} , \pm 2 {T}_{s} , … , \\ 0 & for all other n\end{matrix}$$

Finally it is shaped using the function s[n] to construct the watermark signal w[n] given by:
w[n]=\tilde{w}ₛ[n]*s[n].

The window shaping function s[n] may for example be raised cosine or bi-phase window functions, which functions are shown in FIGS. 12A and 12B, respectively.

As mentioned earlier more than one sub-band might be selected for receiving the same watermark. Different watermarks can also be embedded in different sub-bands.

The device and method described above functions well in that a watermark can be embedded in a preferably inaudible manner, while still being detectable. However, note that time domain multiplication of sub-band samples with the watermark signal will lead to a bandwidth extension. Since the sub-band samples are critically sampled, this extra bandwidth will fold back into the frequency spectrum of the band in question, which may lead to aliasing distortions. The effect will depend on the bandwidth of the watermark sequence and the characteristics of the audio signal. A device for avoiding this aliasing is shown in FIG. 5.

In FIG. 5, a modified watermark inserting unit 45 is shown. It should be understood that this unit replaces the watermark inserting unit 18 shown in FIG. 1. The watermark w[n] is here supplied to a first upsampling unit 46. The upsampling unit comprises a cascade of a sample rate increaser and a low-pass interpolation filter and can, as an example, upsample the watermark with a factor of two before the watermark w[n] is provided to the embedder unit 22, which is shown in FIG. 2B. In the same way the sub-band sample signals xᵢ₋₁[n], xᵢ[n], and xᵢ₊₁[n] are upsampled in corresponding upsampling units 46, using the same upsampling factor before supplying to the embedder unit 22. The embedder unit works as before. The output from each embedder unit is however provided to a downsampling unit 48, which comprises a cascade of a low-pass anti-aliasing filter and a sample rate decreaser. Each downsampling unit 48 downsamples the signal received from an embedder unit 22 using a downsampling factor equal to the one used in the upsampling units 46 before being provided to the quantisation unit 14. In this way, the overall aliasing effect is reduced.

This solution has the advantage of significantly removing or attenuating the aliasing effects described above. In order for this to work the bandwidth of the watermark cannot exceed that of the sub-band in question. It is however important that the down- and upsampling units use the same sample conversion factors. From a computational complexity point of view this solution is however not optimal. Moreover, the aliasing terms caused by the watermarking procedure are simply discarded.

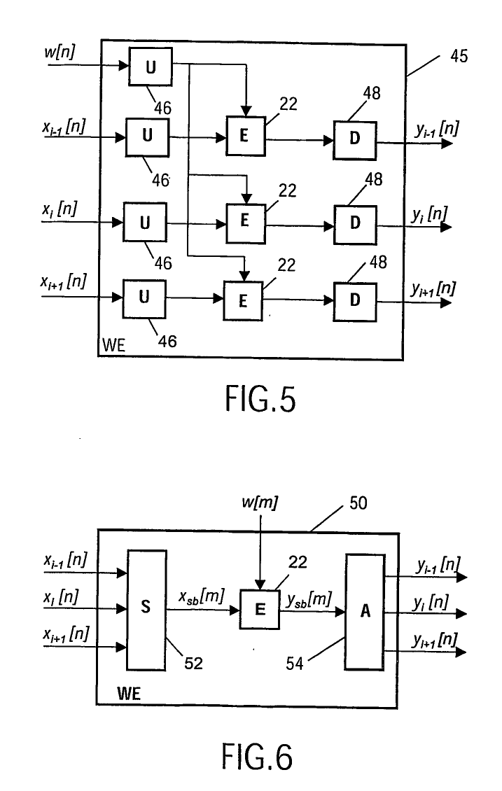

An alternative inserting unit according to a third embodiment of the invention for providing basically the same result is shown in a block schematic in FIG. 6. The inserting unit 50 here comprises a synthesis filter S (unit 52), which receives the sub-band signals xᵢ₋₁[n], xᵢ[n], and xᵢ₊₁[n] and merges these sub-band signals into a single band limited signal x_{sb}[m]. The single signal is then supplied to the embedder unit 22, which embeds the watermark w[m] in the signal x_{sb}[m]. The watermarked signal y_{sb}[m] is then supplied to an analysis filter A unit 54, which splits it into different watermarked sub-band signals yᵢ₋₁[n], yᵢ[n] and yᵢ₊₁[n], which are provided in the same sub-bands as the input sub-band signals were provided in. These watermarked sub-band signals are then supplied to the quantisation unit 14 of FIG. 1.

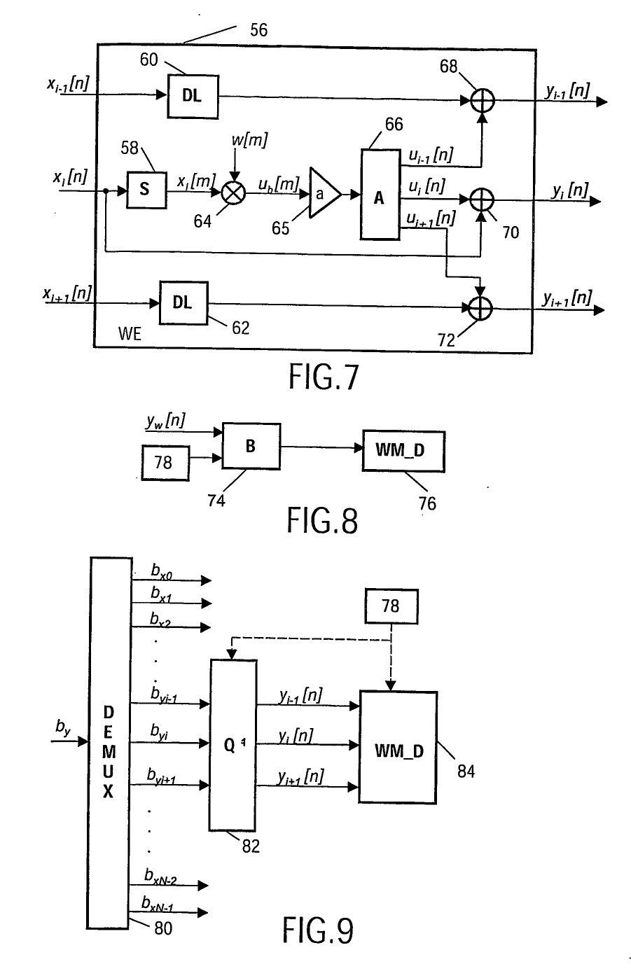

A fourth and preferred embodiment of the invention for embedding a watermark will now be described in relation to FIG. 7. This embodiment is an equivalent to the embodiment shown in FIG. 6, however with the added advantage that, in FIG. 7, one can embed different watermarks in the different sub-bands and hence it is also suited for embedding frequency domain watermarks.

In this embodiment the input signal xᵢ[n] is modulated and therefore receives a watermark. The bandwidth extension due to this operation is covered by spreading this energy in the neighbouring sub-band signals

xᵢ₋₁[n] and xᵢ₊₁[n]. In order to achieve this the neighbouring sub-band samples xᵢ₋₁[n] and xᵢ₊₁[n] are provided to respective delay units 60 and 62, and the delayed sub-band signals are thereafter provided to adding units 68 and 72. The sub-band signal xᵢ[n], which is to receive a watermark, is supplied to a synthesis filter S unit 58, which upsamples the signal and outputs the signal xᵢ[m]. The synthesis filter unit 58 is connected to a multiplying unit 64 where the input signal xᵢ[m] is multiplied with the watermark w[m] for providing a content dependent watermark signal u_{b}[m]. The content dependent watermark signal u_{b}[m] is then scaled with a scaling factor α by a scaling unit 65. Due to the modulation effect, the signal u_{b}[m] thus has a bandwidth which may exceed the bandwidth of the given sub-band signal. The frequency components extending beyond the sub-band bin of band i are therefore added to the neighbouring sub-bands as indicated in the figure. Therefore the output u_{b}[m] of the scaling unit 65 is provided to an analysis filter A unit 66, which splits the watermarked signal u_{b}[m] into three sub-band signals uᵢ₋₁[n], uᵢ[n] and uᵢ₊₁[n] applying the appropriate down sampling factor. The splitting is here done such that the frequency band of the signal uᵢ₋₁[n] corresponds to the frequency band of signal xᵢ₋₁[n] and the frequency band of the signal uᵢ₊₁[n] corresponds to the frequency band of signal xᵢ₊₁[n], while the frequency band of the signal uᵢ[n] corresponds to the frequency band of signal xᵢ[n]. The analysis filter then supplies the signal uᵢ₋₁[n] to adding unit 68 for adding to signal xᵢ₋₁[n] for obtaining the output signal yᵢ₋₁[n], and the signal uᵢ₊₁[n] to adding unit 72 for adding to signal xᵢ₊₁[n] for obtaining the output signal yᵢ₊₁[n]. The analysis filter also supplies signal uᵢ[n] to an adding unit 70, which also receives signal xᵢ[n]. The adding unit 70 thereafter supplies signal yᵢ[n]. All these output signals are then supplied to quantisation unit 14 of FIG. 1.

In this way the aliasing term is appropriately taken care of and the watermark is more easily detected. Moreover no watermark information is lost, which makes the watermark more detectable. In order for this to work, the filter unit 66 need to be sufficiently similar to the filter unit used in a corresponding audio decoder.

It should be realised that the upsampling and downsampling factors, can be selected freely, but are for best results dependent on the number of sub-bands involved. The watermark embedding was in the fourth embodiment essentially performed in one sub-band. It should however be realised that the embedding can in a straightforward manner be extended for more sub-bands. The number of bands can for instance be extended to cover all the sub-bands except the highest and the lowest ones, although this is often not attractive because of audibility reasons.

Now the detection of a watermark will be described. Watermarks can be detected both in the PCM domain as well as in the bit-stream or compressed domain, which two methods are summarized in FIGS. 8, 9 and 10. The functioning of the device in FIG. 8 will now be described with reference also being made to FIG. 4, which shows a flowchart of the detection method. FIG. 8 shows a block schematic of a device for a PCM domain detection of a watermark embedded according to the invention. This means that the bit-stream has been converted to PCM samples as a result of a prior processing. First PCM samples y_{w}[n] having an embedded watermark are provided to a bandpass filter 74, step 40. The filter coefficients are selected by a control unit 78 to define a frequency band, which preferably corresponds to the sub-bands where the watermark was inserted, step 42, and then the bandpass filtered PCM signal is provided to watermark detector 76, which uses a know watermark detecting function WM_D for detecting watermarks, step 44.

A device for detecting watermarks in the bit-stream domain is shown in a block schematic in FIG. 9. The device includes a demultiplexing unit 80, which demultiplexes the potentially watermarked input bit-stream by into different sub-bands b_{y0}−b_{yN-1}; a dequantisation unit 82 that converts the sub-band bit-streams b_{yi-1}, b_{yi}, b_{yi+1}, corresponding to the watermark band, into sub-band signals yᵢ₋[n], yᵢ[n], yᵢ₊₁[n]. A watermark detector 84 is then set by a control unit 78 to detect watermarks in the sub-bands having the embedded watermark. The control unit 78 also controls the dequantisation unit 82. This detection method can in a straightforward manner be made for fewer or more sub-bands than the ones shown.

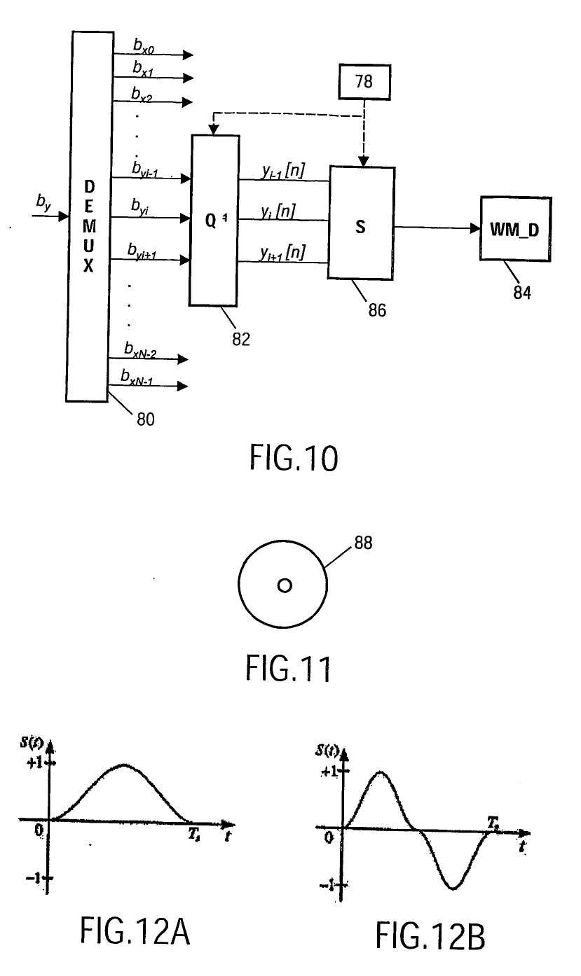

An alternative device for detecting watermarks in the bit-stream domain is shown in a block schematic in FIG. 10. FIG. 10 includes all the units shown in FIG. 9. In addition to these units, the device in FIG. 10 also includes a synthesis filter 86, which receives the sub-band signals yᵢ₋₁[n], yᵢ[n], and yᵢ₊₁[n] and merges these sub-band signals into a single signal. The single signal is then supplied to the watermark detector 84, which detects the watermark in the single signal. The control unit 78 here also controls the synthesis filter 86.

A signal including samples having the watermark embedded can be provided in many ways. It can be provided on a computer readable medium such as on a hard disc, but it can just as well be provided on other types of mediums such as an optical disc like a CD-record, of which one 88 is shown in FIG. 11.

The present invention has many advantages. A watermark inserted according to the invention can be detected both in the PCM domain as well as in the compressed domain. The watermark is furthermore provided in the bit-stream domain, which means that there is no need to decode the signal to the PCM domain, for embedding a watermark and then performing the coding. Such a method would introduce additional artefacts and take a longer time. The watermark embedding according to the invention is furthermore less complex regarding computational power. The watermark embedding according to the invention is particularly well suited for forensic tracking, where watermarks are embedded in e.g. files distributed via an Electronic Content Delivery System, and used to track for instance illegal copied content on the Internet, since the content provided there is in many cases in the form of bit-streams. It can also be used with good results for monitoring broadcast stations or for authentication purposes etc.

The invention can be varied in many ways. A watermark can as was also mentioned previously be embedded in both the scaled and unscaled sub-band samples. Different scaling factors can as mentioned also be used. Only the sub-band bit-streams that were to include a watermark were converted in the dequantisation unit. It should be realised that as an alternative all sub-band bit-streams could be converted as well. Moreover, the embedded data need not be a watermark, but can be any type of additional data that is interesting to embed in an audio signal. The selection of subbands where watermarks are embedded can furthermore be changed from time to time in the audio signal, for instance in dependence on the properties of the signal. In this case the information about selected sub-bands can also be coded in the audio signal. The invention has been described in relation to audio, but it should be realised that it is not limited to this, but can be applied also for other media signals such as images or video. Therefore the invention is only to be limited by the following claims.

The invention can be summarized as follows. The present invention relates to methods, devices, a media signal and a recorded medium for watermarks embedded in the sub-band domain of compressed media. Watermarks (w[n]) are embedded into the sub-band signals (xᵢ₋₁[n], xᵢ[n], xᵢ₊₁[n]) of at least one selected sub-band of a compressed bit-stream (bₓ) using a watermark inserting unit (18). In this way there is no need to fully decode and re-encode the media signal for embedding the watermark.

The watermark is embedded in selected sub-bands (e.g. sub-bands 7-15 of 32). In a preferred embodiment, the selected sub-bands are upsampled before embedding and downsampled therafter so as to avoid aliasing. The invention also allows embedding multiple watermarks in different sub-bands (e.g. one watermark in sub-bands 7-11, and a different watermark in sub-bands 12-16).

1. A method of embedding additional data into the bit-stream of a media signal comprising the steps of:
obtaining (30) a number of sub-band bit-streams of an input bit-stream,
converting (31) at least one sub-band bit-stream into a primary sub-band signal that is semantically compatible with said additional data, and
modifying (32) said sub-band signal with said additional data, in order to provide an output bit-stream carrying said embedded additional data.

2. Method according to claim 1, wherein the step of obtaining sub-band bit-streams comprises splitting the input bit-stream into a number of sub-band bit-streams.

3. Method according to claim 1, further including the step of converting (34) the modified sub-band signal into a corresponding sub-band bit-stream, and combining (38) the modified sub-band bit-stream with the unmodified sub-band bit-streams into a single output bit-stream carrying said additional data.

4. Method according to claim 1, further including the step of delaying (36) the unmodified sub-band bit-streams.

5. Method according to claim 1, further comprising the step of selecting at least one sub-band which is to include additional data.

6. Method according to claim 1, wherein the additional data is provided in the time, frequency or spatial domain.

7. Method according to claim 1, further including the step of upsampling (U) the primary sub-band signal to obtain a secondary sub-band signal; the step of modifying said secondary sub-band signal to obtain a modified secondary sub-band signal; and the step of downsampling (D) said modified secondary sub-band signal.

8. Method according to claim 7, wherein the step of upsampling also comprises upsampling (U) the additional data before performing the step of modifying.

9. Method according to claim 7, further comprising the step of splitting said modified secondary sub-band signal into a number of primary modified sub-band signals; the step of downsampling the primary modified sub-band signals; and the step of adding each modified primary sub-band signal to a corresponding unmodified primary sub-band signal for provision in a number of neighbouring sub-band bit-streams.

10. Method according to claim 9, further comprising the step of scaling said modified secondary sub-band signal prior to the step of splitting.

11. Method according to claim 1, wherein the step of converting comprises converting at least two of the sub-band bit-streams into primary sub-band signals that are semantically compatible with the intended additional data and further comprising the step of merging (S) said at least two primary sub-band signals into a single secondary sub-band signal and performing the step of modifying on said secondary sub-band signal.

12. Method according to claim 10, further comprising the steps of splitting said modified secondary sub-band signal into at least two modified primary sub-band signals, converting the modified primary sub-band signals into modified sub-band bit-streams and combining the modified and non-modified sub-band bit-streams into a single output bit-stream carrying said additional data.

13. A method of detecting additional data provided in a media signal comprising the steps of:
selecting (42) a frequency range at least approximately corresponding to at least one sub-band signal where the additional data is embedded, and
detecting (44) the additional data.

14. Method according to claim 13, wherein the step of selecting is performed by temporal, spatial or spectral filtering of the media signal.

15. Method according to claim 13, wherein the media signal is a compressed media bit-stream and the step of selecting is performed through splitting the bit-stream into a number of sub-band bit-streams, selecting the bit-stream of at east one sub-band where additional data is embedded and detecting the additional data in the sub-band.

16. Method according to claim 15, further comprising the step of converting the selected sub-band bit-stream into a corresponding sub-band signal and performing the step of detecting on the sub-band signal.

17. Method according to claim 16, wherein the step of converting the sub-band bit-stream to a sub-band signal comprises converting at least two of the sub-band bit-streams into primary sub-band signals and further comprising the step of merging (S) said at least two primary sub-band signals into a single secondary sub-band signal and performing the step of detecting on said secondary sub-band signal.

18. A device for embedding additional data in the bit-stream of a media signal comprising:
a unit (12) for converting at least one sub-band bit-stream, which is to carry additional data and is related to an input bit-stream, into a primary sub-band signal semantically compatible with the intended additional data, and
at least one data inserting unit (18; 56) for modifying said sub-band signal with additional data for provision in an output bit-stream.

19. Device according to claim 18, further comprising a unit (10) for receiving an input bit-stream and splitting it into a number of sub-band bit-streams.

20. Device according to claim 19, further comprising a unit (14) for converting the modified sub-band signal to output sub-band bit-streams and a unit (16) for combining sub-band bit-streams including modified and unmodified sub-band bit-streams in order to provide an output bit-stream carrying said additional data.

21. Device according to claim 18, further comprising at least one unit (46; 58) for upsampling a primary sub-band signal to obtain a secondary sub-band signal before performing modification and at least one unit (48; 66) for downsampling the modified secondary sub-band signal.

22. Device according to claim 21, further comprising a unit (46) for upsampling the additional data before performing embedding.

23. Device according to claim 21, wherein the unit (66) for downsampling is further arranged to split the modified secondary sub-band signal into a number of primary sub-band signals and further comprising:
a number of adding units (68, 70, 72) corresponding to the number of split signals for adding the split signals to a number of neighbouring sub-band signals.

24. Device according to claim 18, wherein the unit (12) for converting at least one sub-band bit-stream to a sub-band signal is arranged to convert at least two sub-band bit-streams into two primary sub-band signals and further comprising a unit (52) for merging the primary sub-band signals into a single secondary sub-band signal for provision to the inserting unit and a unit (54) for splitting the modified secondary sub-band signal into at least two modified primary sub-band signals in order to provide sub-band signals having additional data.

25. A device for detecting additional data provided in a media signal, comprising: a control unit (78) for selecting a frequency range at least approximately corresponding to at least one sub-band where the additional data is provided, and
an additional data detector (76; 88) for detecting the additional data.

26. Device according to claim 25, further comprising at least one unit (74) for filtering the media signal in the temporal, spectral or spatial domain.

27. Device according to claim 25, wherein the media signal is a compressed media bit-stream and further comprising a unit (80) for splitting the bit-stream into a number of sub-band bit-streams and the control unit (78) is arranged to connect the additional data detector (84) for receiving signals of a selected sub-band where additional data is embedded and detecting the additional data in the signals of the sub-band.

28. Device according to claim 27, further comprising a unit (82) for converting at least one sub-band bit-stream which includes additional data into a sub-band signal.

29. Device according to claim 28, wherein the unit (82) for converting the sub-band bit-stream to a sub-band signal is arranged to convert at least two of the sub-band bit-streams into sub-band signals and further comprising a unit (86) for merging (S) said at least two primary sub-band signals into a single secondary sub-band signal and the detector is connected to the unit for merging primary sub-band signals for performing the detection on said secondary sub-band signal.

30. A media signal (b_{y}; y_{W}[n]) having additional embedded data (w[n]), wherein the additional data is embedded in at least one sub-band signal (xᵢ₋₁[n], xᵢ[n], xᵢ₊₁[n]) of the media signal.

31. A recorded medium (88) having additional embedded data (w[n]) in a media signal, wherein the additional data is embedded in at least one sub-band signal (xᵢ₋₁[n], xᵢ[n], xᵢ₊₁[n]) of the media signal.
